(19) United States
(12) Patent Application Publication
(10) Pub. No.: US 2025/0321820 A1
(43) Pub. Date: Oct. 16, 2025

(54) DATA-RECORDING SYSTEM, STORAGE, AND STORAGE CONTROL METHOD

(71) Applicant: Panasonic Intellectual Property Management Co., Ltd., Osaka (JP)

(72) Inventor: Hideaki YAMASHITA, Kyoto (JP)

(21) Appl. No.: 18/870,563

(22) PCT Filed: May 10, 2023
(86) PCT No.: PCT/JP2023/017611

§ 371 Date: Nov. 29, 2024

(30) Foreign Application Priority Data
May 30, 2022 (JP) 2022-088046

(51) Int. Cl. G06F 11/07

(52) U.S. Cl. CPC G06F 11/0772; G06F 11/073

(57) ABSTRACT

A data-recording system comprises a storage and a storage control device. The storage has flash memory having a plurality of blocks, each of which is a unit for erasing data. Each of the blocks includes a plurality of pages, each of which is a unit for recording data. In a case where to-be-recorded data can be successively recorded in a set area, the storage control device issues a notification of the completion of recording in the set area for a unit of the number of recording instructions required to record the to-be-recorded data in the set area. In a case where to-be-recorded data cannot be successively recorded in the set area, the storage control device issues a notification of an error in recording in the set area for a unit of the number of recording instructions required to record the to-be-recorded data in the set area.

### DESCRIPTION

### Technical Field

The present disclosure relates to a data-recording system for recording data on storage, a storage for recording data, and a storage control method of recording data.

### Background Art

A storage referred to as a solid-state drive (SSD) is known as a storage that records data. An SSD has a semiconductor device referred to as a NAND flash memory as a data recording area. A NAND flash memory includes a large number of memory elements, and data (bit data) is recorded in the memory elements.

The recording area of a NAND flash memory has a plurality of blocks, each of which is a unit for erasing data, and each block has a plurality of pages. Data is recorded in the NAND flash memory in a unit of the page. That is, to-be-recorded data is divided into a plurality of fragments, and one fragment is recorded in one page, whereby all of the data is recorded in the NAND flash memory.

If recording a data fragment on a certain page fails, recording of the fragment on this page is skipped and the fragment that failed to be recorded is recorded on another page in the current block or on a page in another block (for example, see Patent Literature 1).

In an SSD, a page in which invalid data was recorded cannot be overwritten to record other data. Therefore, in an SSD, all pages of the block including the page in which the invalid data was recorded must be made free pages. If this block contains valid data, the valid data must be moved to another block, and all pages of the block must be made free pages (garbage collection).

### PRIOR ART LITERATURE

### Patent Literature

### [Patent Literature 1] Japanese Laid-open Patent Publication 2019-215777

### DISCLOSURE OF THE INVENTION

### Problems to be Solved by the Invention

Conventionally, in a case where recording of a fragment on a specific page fails, if the fragment is recorded on another page, the data is recorded in a fragmented state. When data is fragmented, originally there would be cases in which, for example, data that can be recorded to fit in one block is recorded across a plurality of blocks.

Thus, when data fragmentation causes one piece of data to be frequently recorded across a plurality of blocks, garbage collection is executed more frequently. Since an operating speed of the storage decreases when garbage collection is executed, it is preferable that the execution of garbage collection be suppressed as much as possible.

An object of the present disclosure is to suppress data fragmentation and suppress the execution of garbage collection in storage having flash memory.

### Means for Solving Problems

The data-recording system of the present disclosure comprises a storage and a storage control device. The storage includes a flash memory and a controller. The flash memory has a plurality of blocks, each of which is a unit for erasing data. The blocks include a plurality of pages, each of which is a unit for recording data. The controller controls the recording of data in the flash memory. The storage control device controls the storage.

In the data-recording system described above, the controller receives a plurality of recording instructions for recording to-be-recorded data in the flash memory from the storage control device. The controller records the to-be-recorded data in the flash memory in accordance with the received plurality of recording instructions.

In a case where the storage control device can successively record the to-be-recorded data in a set area, the storage control device determines that data recording in the set area has been successful. The set area is an area in the flash memory that has a predetermined number of pages. In a case where the storage control device has determined that data recording in the set area has been successful, the storage control device issues a notification that data recording in the set area is complete, for a unit of the number of recording instructions required to record the to-be-recorded data in the set area.

In a case where the storage control device is unable to successively record to-be-recorded data in a set area, the storage control device determines that recording of data in the set area has failed. In a case where the storage control device has determined that recording of data in the set area has failed, the storage control device issues a notification of an error in recording data in the set area, for a unit of the number of recording instructions required to record the to-be-recorded data in the set area.

### Effects of Invention

In the data-recording system of the present disclosure, in a case where the storage control device is able to successively record to-be-recorded data in a set area of the storage, the storage control device determines that data recording in the set area has succeeded, and issues a notification of the completion of data recording in the set area, for a unit of the number of recording instructions required to record the to-be-recorded data in the set area. In a case where to-be-recorded data cannot be successively recorded in the set area of the storage, the storage control device determines that data recording in the set area has failed, and issues a notification of an error in data recording in the set area, for a unit the number of recording instructions required to record the to-be-recorded data in the set area. In other words, in a case where recording of to-be-recorded data has failed for any recording instruction for recording the to-be-recorded data in a specific set area, it is determined that data recording has failed not only for the recording instruction for which data recording failed, but for all recording instructions for recording the to-be-recorded data in the specific set area. This can suppress data fragmentation in the storage and suppress the execution of garbage collection. As a result, any decrease in the operating speed of the storage can be suppressed.

### BRIEF DESCRIPTION OF THE DRAWINGS

FIG. 1 is a diagram of a configuration of a data-recording system;

FIG. 2 is a diagram of a configuration of an information-processing device;

FIG. 3 is a diagram of a configuration of a storage control device;

FIG. 4 is a diagram of a configuration of storage;

FIG. 5 is a diagram of a configuration of a recording area;

FIG. 6 is a flowchart of operation of the information-processing device;

FIG. 7 is a flowchart of operation of the storage control device;

FIG. 8 is a diagram of operation of storage;

FIG. 9 is a diagram indicating the transmitting and receiving of signals during data recording operation;

FIG. 10 is a diagram of an example of in a case where data recording in a set area has succeeded (i.e., a completion condition is met);

FIG. 11 is a diagram of an example of in a case where data recording in a set area has failed;

FIG. 12 is a diagram schematically depicting an example of re-recording data that had failed to be recorded;

FIG. 13 is a diagram schematically depicting the recording of data in the data-recording system; and

FIG. 14 is a diagram schematically depicting the recording of data in a conventional example.

### BEST MODE FOR CARRYING OUT THE INVENTION

Embodiments are described in detail below with reference made to the drawings as appropriate. However, there are cases of omitting descriptions that are more detailed than necessary. For example, there are cases of omitting detailed descriptions of matters that are already well known and redundant descriptions of configurations that are essentially the same. This is to avoid making the following descriptions unnecessarily redundant and to facilitate understanding by those skilled in the art. The inventors provide the accompanying drawings and the following descriptions to enable those skilled in the art to fully understand the present disclosure, and in doing so, have no intention to limit the subject matter recited in the claims.

In the present disclosure, “recording” data means writing data, and “recording data successively” means that data is recorded with no free pages between fragments of data.

### [1. Data-Recording System]

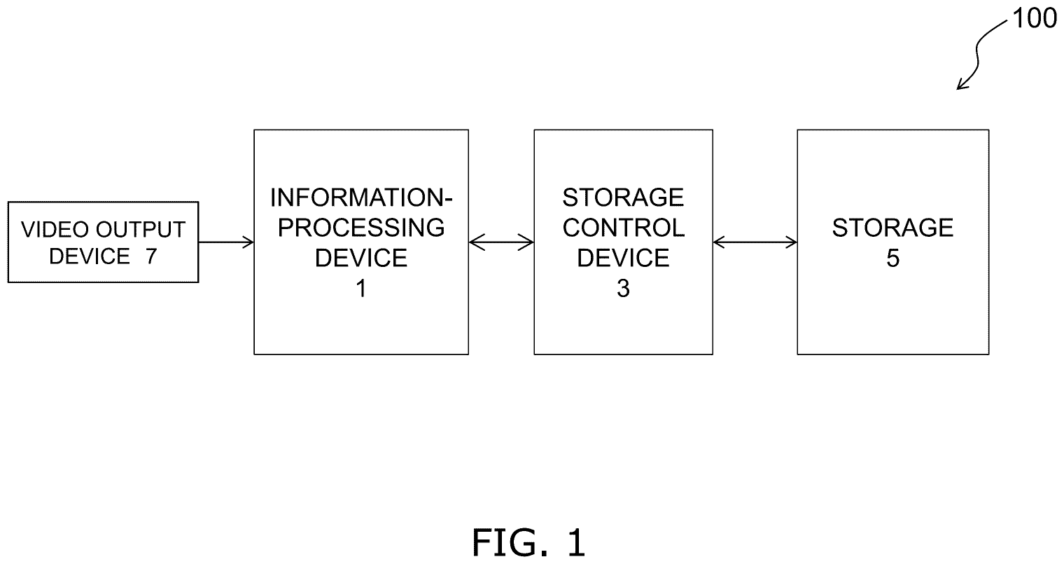

A data-recording system 100 of the present disclosure is described below with reference to the drawings. The data-recording system 100 is a system that stores predetermined data on storage 5. A configuration of the data-recording system 100 is described using FIG. 1. FIG. 1 is a diagram of the configuration of the data-recording system 100. The data-recording system 100 comprises an information-processing device 1, a storage control device 3, and the storage 5.

The information-processing device 1 is a device that acquires data stored on the storage 5. The information-processing device 1 is connected to a video output device 7. The video output device 7 is a device that outputs video to an external destination. That is, the information-processing device 1 acquires the video outputted by the video output device 7 as data recorded on the storage 5.

The video output device 7 is a video capture device provided with, for example, a camera that captures predetermined video, a microphone that acquires audio of the predetermined video, etc. Alternatively, the video output device 7 may be, for example, a media server that records a large number of videos, or a video-receiving device that acquires videos carried by signals such as radio waves. The video acquired by the video output device 7 is, for example, high-quality video such as 4K video in an uncompressed format.

To-be-recorded data on the storage 5, which is connected to the storage control device 3, is temporarily transmitted from the information-processing device 1 to the storage control device 3 and is recorded on the storage 5 by the storage control device 3.

The storage control device 3 is connected to the information-processing device 1 and the storage 5 via a network, and the storage control device 3 controls transmission and reception of data and instructions between the information-processing device 1 and the storage 5. In addition, in a case where the recording of data in the storage 5 is completed, the storage control device 3 issues a notification to the information-processing device 1 of the completion of the data recording. In a case where the recording of data in the storage 5 fails, the storage control device 3 issues a notification to the information-processing device 1 of an error in data recording.

The storage 5 is a device that is configured to record data. The storage 5 has a flash memory, which is nonvolatile memory of a semiconductor, as an area for recording data. The storage 5 is a solid-state drive (SSD).

In the example of the data-recording system 100 shown in FIG. 1, the storage control device 3 and the storage 5 are configured as separate devices. However, not limited to this, the storage control device 3 and the storage 5 may be disposed in one housing to form one device. That is, the storage 5 may be included in the storage control device 3. In addition, the information-processing device 1 and the video output device 7 may be disposed in one housing to form one device.

### [2. Information-Processing Device]

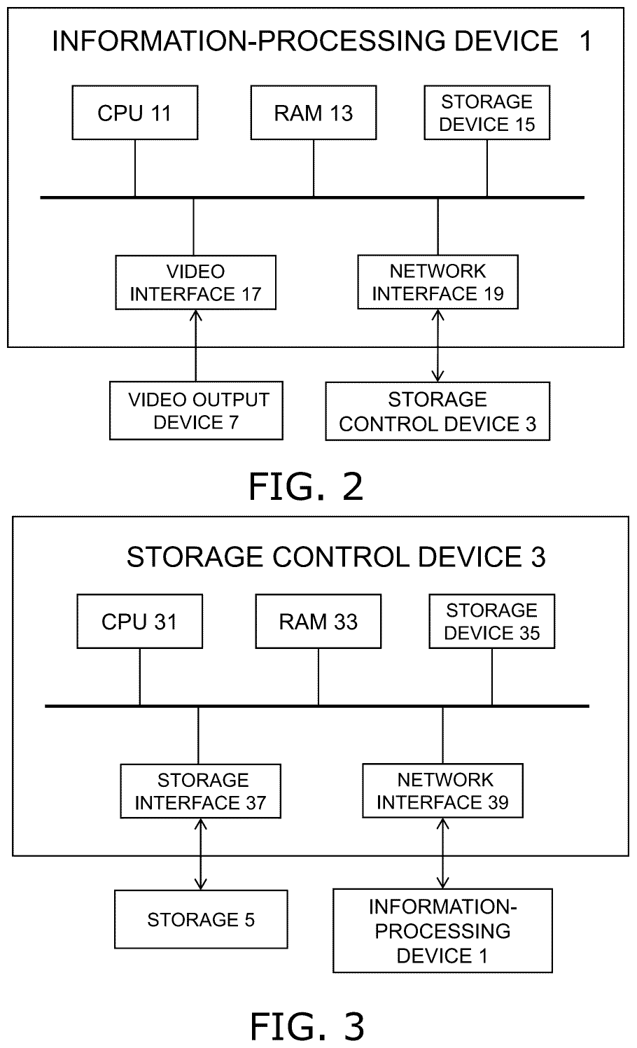

A configuration of the information-processing device 1 shall be described using FIG. 2. FIG. 2 is a diagram of a configuration of the information-processing device 1. The information-processing device 1 has a CPU 11, a RAM 13, a storage device 15, a video interface 17, and a network interface 19.

The CPU 11 executes various processes in the information-processing device 1. Specifically, the CPU 11 executes, inter alia, processes related to recording data in the storage 5. The CPU 11 executes various processes in accordance with commands indicated in a program stored in the storage device 15. Some of the processes may be realized by hardware installed in the CPU 11. The CPU 11 generates instructions for executing various processes. The RAM 13 temporarily stores data, etc. The instructions generated by the CPU 11 and the data transmitted to and received from the storage control device 3 are temporarily stored in the RAM 13.

The storage device 15 includes a ROM, a hard disk (HDD), a solid-state drive (SSD), etc. The storage device 15 stores, inter alia, programs executed by the CPU 11, settings related to the processes of the information-processing device 1, and parameters used for the processes.

The video interface 17 is an interface for connecting the information-processing device 1 and the video output device 7. The video interface 17 is an interface for connecting video-related devices, such as, for example, interfaces conforming to the Serial Digital Interface (SDI) standard.

The network interface 19 connects the information-processing device 1 and other devices via a network such as a WAN or LAN. The storage control device 3 is connected to the network interface 19 as shown in FIG. 2.

The network interface 19 allows data, etc., to be transmitted and received directly between the RAM 13 of the information-processing device 1 and RAM of other devices by remote direct memory access (RDMA). This enables high-speed data transmission and reception between the information-processing device 1 and other devices. The network interface 19 is, for example, a Gigabit Ethernet (registered trademark) interface.

In the information-processing device 1, the video output device 7 may be connected to the network interface 19 instead of the video interface 17.

### [3. Storage Control Device]

A configuration of the storage control device 3 is described using FIG. 3. FIG. 3 is a diagram of a configuration of the storage control device 3. The storage control device 3 has a CPU 31, a RAM 33, a storage device 35, a storage interface 37, and a network interface 39.

The CPU 31 executes various processes in the storage control device 3. The CPU 31 executes various processes in the storage control device 3 by executing commands indicated in programs stored in the storage device 35. Some of the processes in the storage control device 3 may be realized by hardware installed in the CPU 31. The RAM 33 temporarily stores data, etc. Temporarily stored in the RAM 33 are, inter alia, instructions for the storage 5 and data transmitted and received between the information-processing device 1 and the storage 5.

The storage device 35 includes a ROM, a hard disk (HDD), a solid-state drive (SSD), etc. The storage device 35 stores, inter alia, programs executed by the CPU 31, settings related to the processes of the storage control device 3, and parameters used for the processes.

The storage interface 37 connects the storage control device 3 and the storage 5. The storage interface 37 is, for example, a PCIe interface that complies with the PCI express standard of the PCI-SIG standard. This allows the storage control device 3 and the storage 5 to transmit and receive data, etc., at high speed using a protocol dedicated to non-volatile memory (non-volatile memory express (NVMe)) using a PCI-express bus. In NVMe, the controller acquires data from the NAND memory using a NAND protocol, converts the data to a PCIe protocol, and transfers the data to a host side. At this point, if a conventional SATA (Serial-ATA) is used, a DMA controller that directly transfers data to the host side converts data from the NAND memory to a SATA protocol, acquires the data, and further converts the data to the PCIe protocol and transfers the data to a host. That is, the NVMe process directly converts from the NAND protocol to the PCIe protocol, and a data transfer processing speed is therefore high.

The network interface 39 connects the storage control device 3 and other devices via a network such as WAN or LAN. The information-processing device 1 is connected to the network interface 39 as shown in FIG. 3. The network interface 39 allows data, etc., to be transmitted and received directly between the RAM 33 of the storage control device 3 and RAM of other devices by RDMA. The network interface 39 can also transmit and receive data at high speed with other devices by using a protocol (NVMe over Fabric (NVMe-oF)) for communication via a network dedicated to solid-state drives. The network interface 39 is, for example, a Gigabit Ethernet (registered trademark) interface.

### [4. Storage]

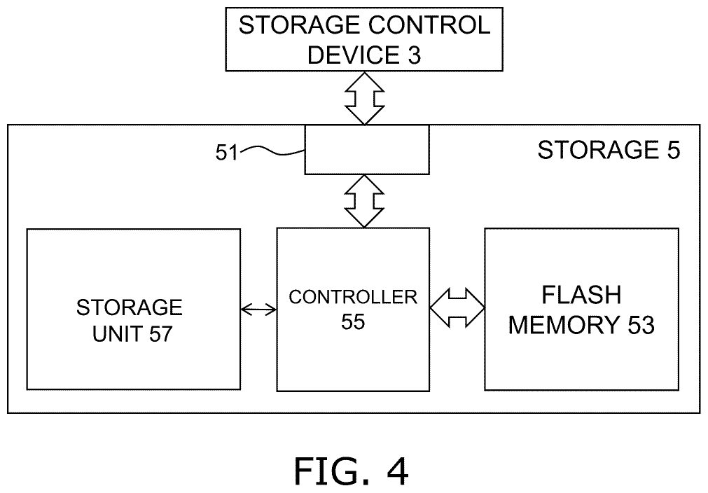

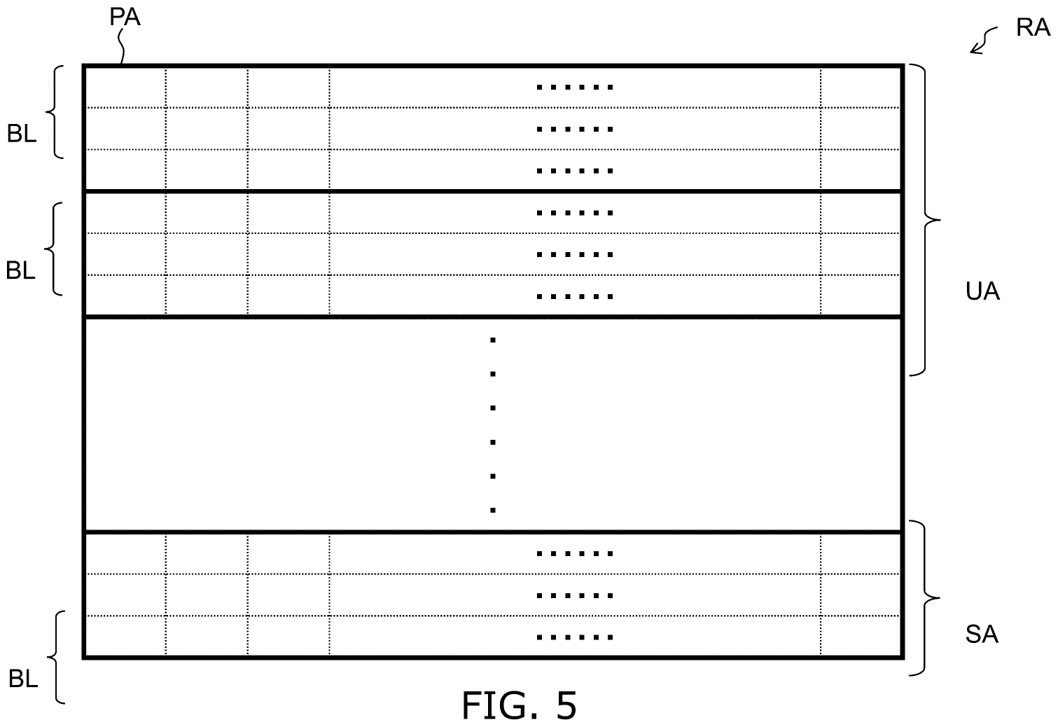

A configuration of the storage 5 is described using FIG. 4. FIG. 4 is a diagram of a configuration of the storage 5. The storage 5 has an access port 51, a flash memory 53, a controller 55, and a storage unit 57. The access port 51 connects the storage control device 3 and the storage 5. A plurality of access ports 51 may be provided, and the storage control device 3 may be connected to one of the plurality of access ports 51. A plurality of access ports 51 may all be connected to the storage control device 3.

The flash memory 53 includes a plurality of NAND flash memories. The flash memory 53 has a recording area RA for recording video. The recording area RA is divided into a plurality of blocks BL as shown in FIG. 5. FIG. 5 is a diagram of a configuration of the recording area RA.

The blocks BL are also referred to as erasure blocks, and the block is a unit of data erasure. Each of the blocks BL is further divided into a plurality of pages PA. The page PA is a unit of data recording. In the flash memory 53, in a case where the data of a block BL is erased, the data contained in this block BL is erased after being moved to another block BL (garbage collection). This makes the block BL a “free block” to which data can be written.

The recording area RA includes a usable area UA and a spare area SA. The usable area UA includes blocks BL on which data can be recorded. The spare area SA is used for the purpose of migration of data contained in the usable area UA by wear leveling process, garbage collection, etc. Recording of data from the information-processing device 1 is prohibited in blocks BL contained in the spare area SA.

The controller 55 executes control related to the storage 5. Specifically, the controller 55 controls the recording of data to the flash memory 53 and the reading of data from the flash memory 53. The controller 55 also executes other processes required for a solid-state drive, such as garbage collection and wear leveling. The controller 55 executes programs stored in the storage unit 57 to execute the above processes. The controller 55 may also realize the above processes via hardware of the controller 55.

The storage unit 57 is provided as memory separate from the flash memory 53, or is a part of the recording area RA, and the storage unit 57 stores various parameters, etc., related to controlling the storage 5. Recorded on the storage unit 57 are, for example, the number of times data is recorded in each block BL, a table associating addresses (logical addresses) designated by external devices with addresses (physical addresses) of blocks BL corresponding to the logical addresses, threshold values representing conditions for executing wear leveling, and the like.

### [5. Recording Operation in Data-Recording System]

### [5-1. Operation of Information-Processing Device]

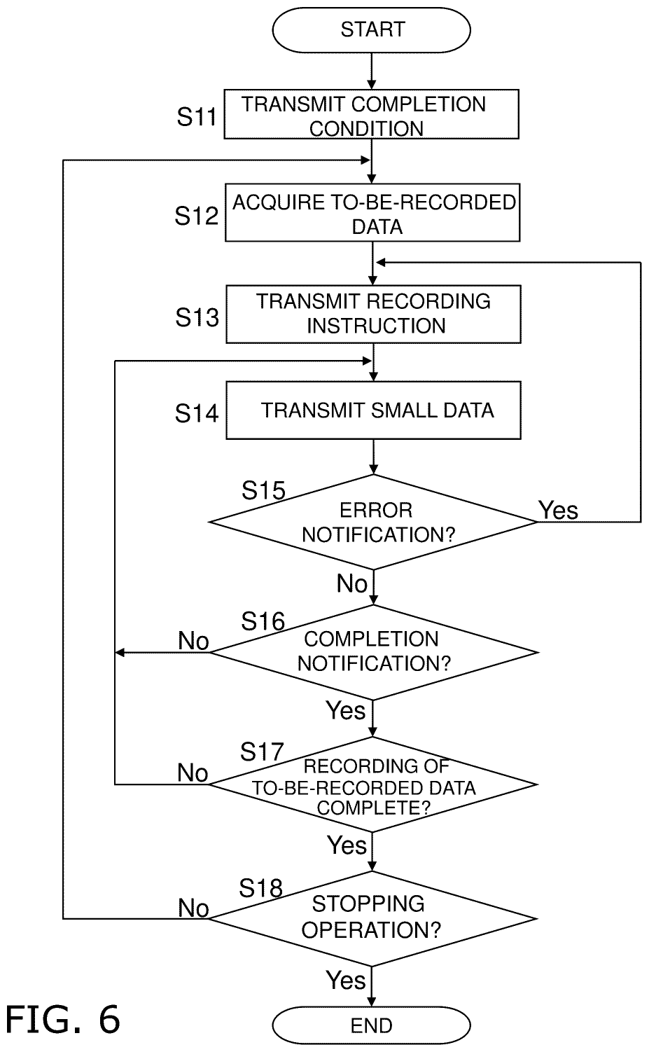

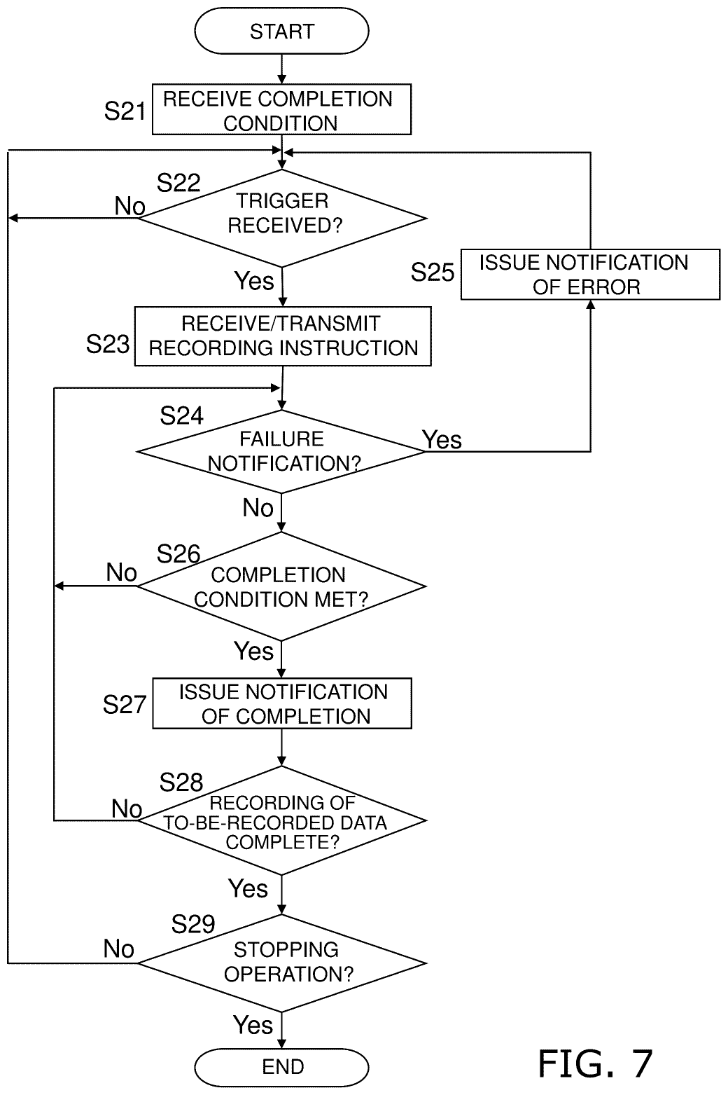

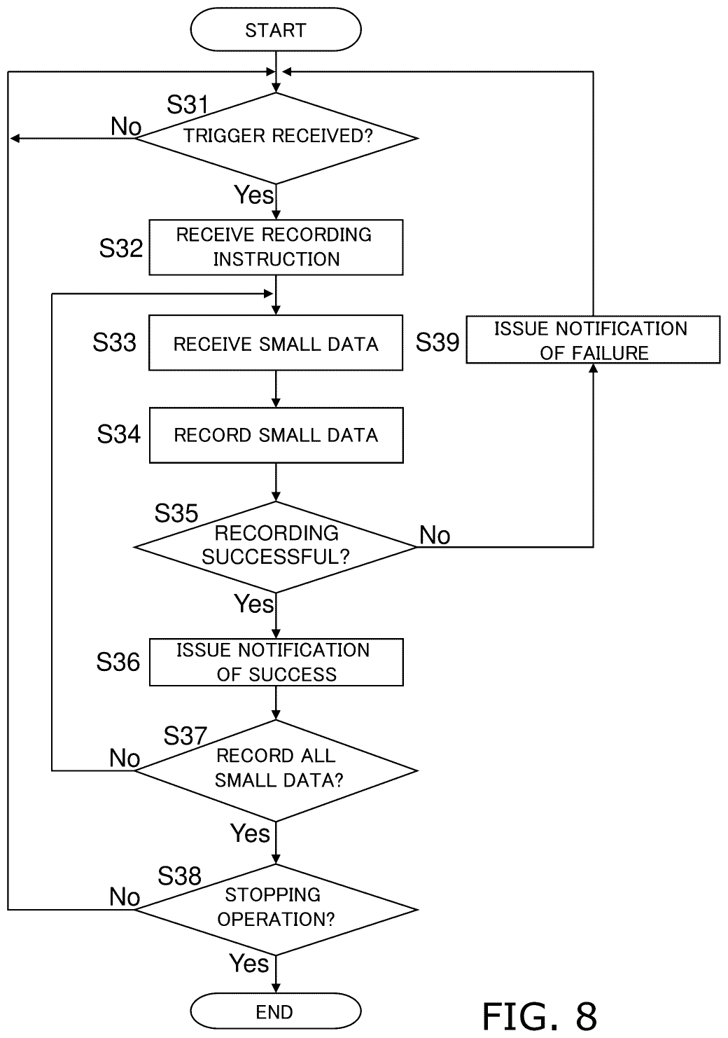

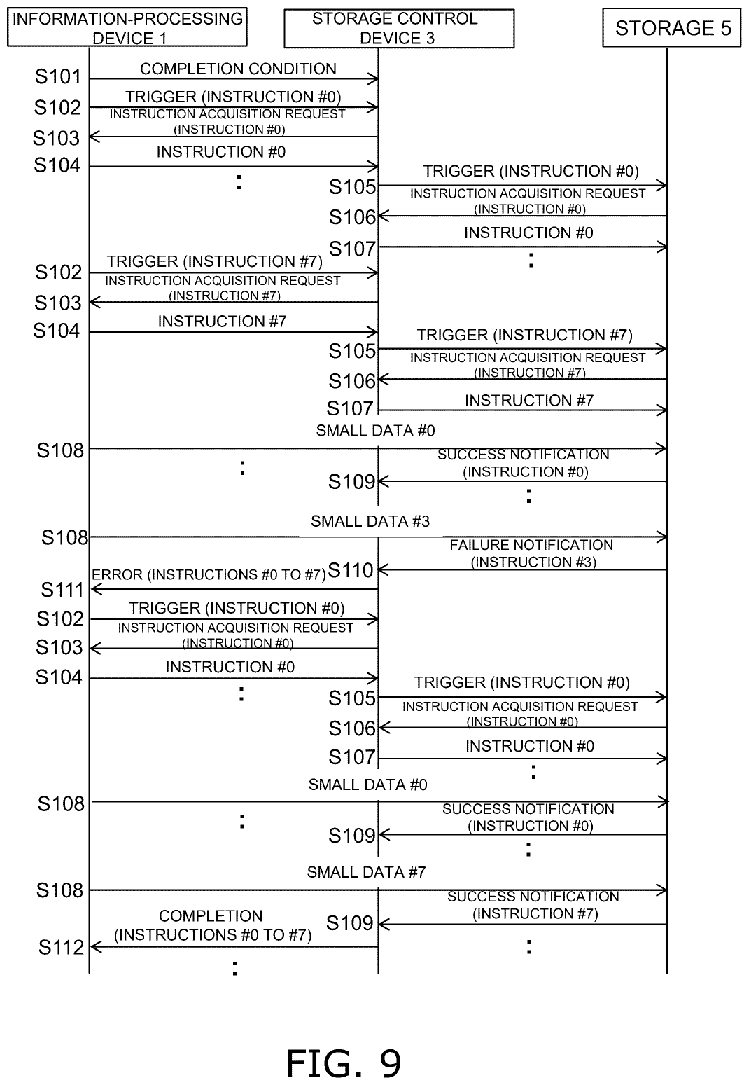

An operation of recording data in the data-recording system 100 is described referring to FIGS. 6 to 9. FIG. 6 is a flowchart of operation of the information-processing device 1. FIG. 7 is a flowchart of operation of the storage control device 3. FIG. 8 is a diagram of operation of the storage 5. FIG. 9 is a diagram indicating the transmitting and receiving of signals during the data recording operation. The operation in the information-processing device 1 is first described referring to FIGS. 6 and 9.

First, the information-processing device 1 transmits a completion condition to the storage control device 3 (step S11 of FIG. 6 and step S101 of FIG. 9). The completion condition is a condition for determining that data recording is complete. Specifically, the completion condition is that data can be recorded successively in a set area of the storage 5 having a predetermined number of pages PA.

The set area of the completion condition can be set in, for example, units of blocks BL of the storage 5. In a case where the set area is one block BL, the completion condition is that data can be recorded successively in the one block BL. Data fragmentation in the block BL can be suppressed by setting the completion condition in this manner. As a result, the number of blocks BL required to record data that is to be recorded (referred to hereinafter as to-be-recorded data) can be prevented from increasing beyond an initial number (the number of blocks BL required in a case where the to-be-recorded data is successively recorded). The set area may also be expressed in units of an amount of data that can be recorded in a block BL. This can realize a set area without regard to boundary positions of the blocks BL.

The CPU 11 next acquires to-be-recorded data (step S12). Specifically, the CPU 11 of the information-processing device 1 acquires video, which is to-be-recorded data, from the video output device 7. The CPU 11 then, as necessary, divides the to-be-recorded data into small data having a predetermined size, and stores the generated small data in the RAM 13. The small data has a size of, for example, about an integer fraction of the size of a block BL. In the following description, it is assumed that the data to be outputted is divided into eight pieces of small data (small data #0 to small data #7). If the to-be-recorded data is equal to or smaller than the size of the small data, the division is not performed.

A recording instruction for recording the to-be-recorded data is generated for each piece of small data and transmitted to the storage control device 3 (step S13, steps S102 to S104). Specifically, the CPU 11 generates a recording instruction for each piece of small data generated in step S12 and stores the recording instructions in the RAM 13. In other words, the CPU 11 generates recording instructions in proportion to the number of pieces of small data divided from the to-be-recorded data. The recording instructions include information indicating a position (address) in the RAM 13 where the small data is stored, and a start position (address) in the page PA where the small data is recorded. The addresses of the page PA included in the plurality of recording instructions are consecutive address values. In other words, the plurality of recording instructions are instructions for successively recording the multiple pieces of small data divided from the to-be-recorded data in the page PA.

For example, if the data to be outputted is divided into eight pieces of small data (small data #0 to small data #7), eight recording instructions (recording instruction #0 to recording instruction #7) corresponding to the pieces of small data are generated.

After generating the recording instructions, the CPU 11 transmits a trigger to the storage control device 3 to prompt the storage control device 3 to acquire the recording instructions (step S102). In response to the trigger, the storage control device 3 acquires the recording instructions stored in the RAM 13 (steps S103 and S104). The recording instructions acquired by the storage control device 3 are transmitted to the storage 5 (steps S105 to S107).

After the recording instructions have been transmitted, the small data recorded in the RAM 13 is sequentially transmitted to the storage 5 via the storage control device 3 (steps S14 and S108). The storage 5 stores the received small data in the pages PA specified by the recording instructions. A fragment-recording operation performed by the storage 5 is described hereinafter.

During transmission of the small data to the storage 5, the CPU 11 of the information-processing device 1 determines whether or not an error notification has been issued from the storage control device 3 (step S15). If an error notification has been issued (“Yes” in step S15, step S111), the CPU 11 decides to execute the following process.

As described hereinafter, in the data-recording system 100, an error notification from the storage control device 3 is issued for a unit of the number of recording instructions required to record data in a specific set area of the storage 5. Therefore, in a case where an error notification is issued from the storage control device 3, the CPU 11 regenerates recording instructions that are the same as the multiple recording instructions for which the error notification was issued, from the beginning (for example, from recording instruction #0), and transmits the recording instructions to the storage control device 3 (step S13, steps S102 to S104). The small data stored in the RAM 13 is then sequentially re-transmitted from the beginning (for example, from small data #0) to the storage 5 (step S14, step S108). As a result, to-be-recorded data (small data) that failed to be recorded is re-recorded in another set area of the storage 5.

If no error notification has been issued (step S15: No), the CPU 11 determines whether or not a notification of completion of the recording of data in the current set area has been issued from the storage control device 3 (step S16). If a notification of completion has not been issued (step S16: No), the CPU 11 determines that recording of the to-be-recorded data in the current set area is still in progress, and continues transmitting the small data stored in the RAM 13 (step S14).

If a completion notification has been issued (“Yes” in step S16), the CPU 11 determines that recording of the to-be-recorded data (small data) in the current set area has ended. The CPU 11 then determines whether or not recording of the to-be-recorded data (i.e., all small data) in the storage 5 is completed (step S17). If recording of the to-be-recorded data in the storage 5 is not completed (“No” in step S17), the operation of the information-processing device 1 returns to step S14. That is, the information-processing device 1 continues transmitting the remaining small to-be-recorded data in the current set area.

If the recording of the to-be-recorded data in the current set area is completed (“Yes” in step S17), the CPU 11 determines whether or not a stopping operation of the information-processing device 1 has been performed (step S18). As long as the stopping operation is not performed (as long as the determination is “No” in step S18), the above steps S12 to S17 are repeatedly executed. If the stopping operation has been performed (“Yes” in step S18), the information-processing device 1 stops operating.

### [5-2. Operation of Storage Control Device]

Operation of the storage control device 3 is next described referring to FIGS. 7 and 9. First, the storage control device 3 receives the completion condition from the information-processing device 1 (step S21). Specifically, the network interface 39 of the storage control device 3 records the completion condition, which was stored in the RAM 13 of the information-processing device 1, in the RAM 33 of the storage control device 3 by RDMA.

The storage control device 3 then determines whether or not the above trigger has been received from the information-processing device 1 (step S22). If the trigger has not been received (“No” in step S22), the storage control device 3 determines that there is no recording instruction to be received and continues to wait.

If the trigger has been received (“Yes in step S22, step S102 of FIG. 9), the storage control device 3 determines that there is a recording instruction to be received, receives the recording instruction from the information-processing device 1, and transmits the recording instruction to the storage 5 (step S23, steps S103 to S107). Specifically, the following process is executed.

In a case where a trigger is received by the storage control device 3, the CPU 31 transmits a request to acquire a recording instruction (a recording instruction acquisition request) to the information-processing device 1 (step S103). In a case where the recording instruction acquisition request is received by the information-processing device 1, the network interface 19 of the information-processing device 1 and the network interface 39 of the storage control device 3 transmit the recording instruction recorded in the RAM 13 of the information-processing device 1 to the RAM 33 of the storage control device 3 via RDMA (step S104).

The CPU 31 then transmits a trigger prompting recording instruction acquisition to the storage 5 (step S105). Having received this trigger, the storage 5 receives the recording instruction stored in the RAM 33 (steps S106 and S107).

The above-described process of transmitting and receiving recording instructions is repeatedly executed in proportion to the number of recording instructions generated by the information-processing device 1, i.e., the number of triggers received.

After recording instructions have been transmitted and received, the small data generated by dividing the to-be-recorded data is sequentially transmitted from the information-processing device 1 to the storage 5 via the storage control device 3 (step S108). The storage 5 records the received small data in the specified page PA of the flash memory 53. During the recording of the to-be-recorded data, a notification that the recording of the small data has succeeded or failed is transmitted from the storage 5 to the storage control device 3 (steps S109 and S110). The storage 5 issues the above notification for each of the plurality of recording instructions (recording instruction #0 to recording instruction #7 in the example of FIG. 9) generated for the to-be-recorded data, as shown in FIG. 9.

In a case where the CPU 31 of the storage control device 3 receives the above notification, the CPU 31 determines whether or not the notification is a notification that data recording has failed (step S24). Specifically, the CPU 31 determines whether or not the notification is a notification that data recording has failed for an intermediate recording instruction among a plurality of consecutive recording instructions for recording small data in a specific set area.

In a case where the storage 5 issues a notification that data recording has failed (step S24: “Yes”, step S110), the CPU 31 determines that the to-be-recorded data cannot be successively recorded in the current set area. In this case, the CPU 31 determines that data recording in the current set area has failed, and issues a notification of an error (step S25, step S111). In the error notification in step S25, the CPU 31 issues a notification of an error for a unit of the number of recording instructions required to record the to-be-recorded data in the current set area. That is, the CPU 31 issues a notification of an error not only for the recording instruction for which the error notification was issued, but also for all recording instructions generated to record data in the current set area.

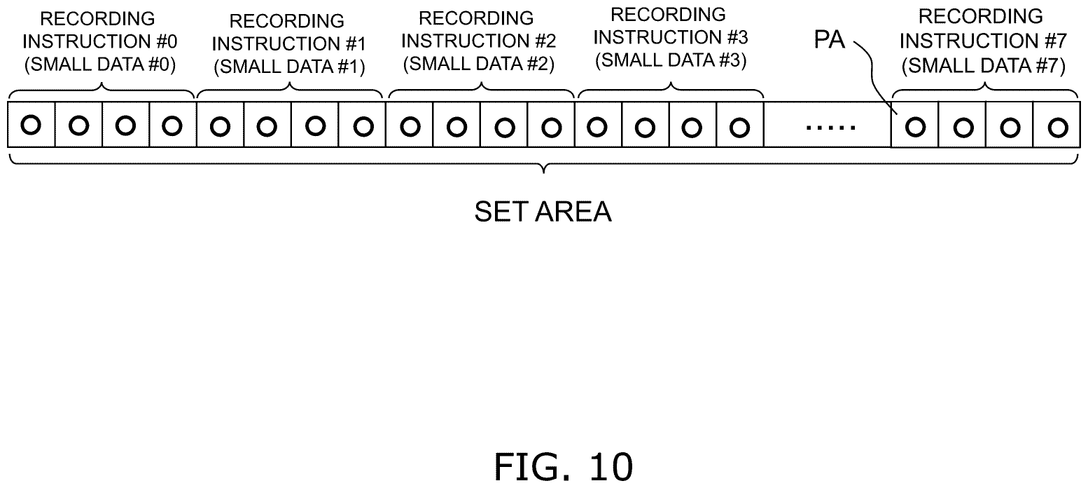

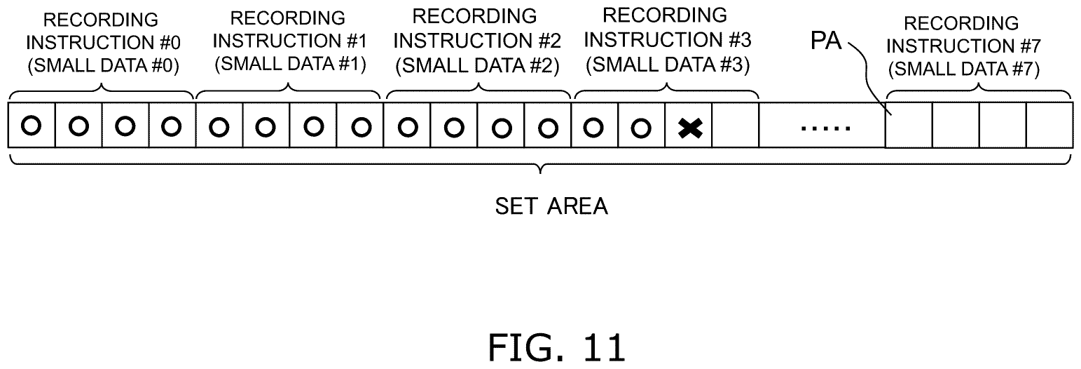

For example, in a case where eight pieces of small data #0 to #7 are successively recorded in one set area (e.g., one block BL) and the recording of data in the set area is assumed to have been successful as shown in FIG. 10, if the recording of small data #3 fails during the recording instruction #3 generated for recording the small data #3 as shown in FIGS. 9 and 11, the CPU 31 issues an error notification not only for the recording instruction #3 but for all of the eight recording instructions #0 to #7 generated to record the small data #0 to #7 in the one set area. In FIGS. 10 and 11, pages PA marked with a circle represent pages PA in which data (fragments, described hereinafter) has been successfully recorded. Pages PA marked with an X represent pages PA in which data recording has failed. FIG. 10 is a diagram of an example of in a case where data recording in a set area has succeeded (i.e., the completion conditions is met). FIG. 11 is a diagram of an example of in a case where data recording in a set area has failed.

After the error notification has been issued as described above, the operation of the storage control device 3 returns to step S22. That is, the storage control device 3 receives a plurality of recording instructions generated by the information-processing device 1 in order to re-record the small data that failed to be recorded in the current recording area in another recording area (steps S102 to S104), and transmits the received plurality of recording instructions to the storage 5 (steps S105 to S107). In addition, the storage control device 3 sequentially receives the small data that failed to be recorded from the information processing-device 1, and sequentially transmits the received small data to the storage 5 (step S108). As a result, small data that failed to be recorded is re-recorded in another set area of the storage 5.

In a case where the storage 5 has issued a notification that the data recording has succeeded (step S24: “Yes,” step S109), the CPU 31 of the storage control device 3 determines whether or not the recorded state of data in the current set area matches the completion condition received in step S21 (step S26). As described above, the completion condition is that data can be successively recorded in the set area. Specifically, the CPU 31 determines that the completion condition is met in a case where the storage 5 issues a notification that data recording has succeeded for all of the consecutive recording instructions for recording small data in the current set area.

If the recorded state of the data in the current set area does not match the completion condition, i.e., if data recording in the current set area is not yet completed (“No” in step S26), the operation of the storage control device 3 returns to step S24. That is, the storage control device 3 sequentially receives the remaining small to-be-recorded data in the current set area from the information-processing device 1 (steps S102 to S104), and sequentially transmits the received small data to the storage 5 (steps S105 to S107). As a result, the storage 5 continues recording the small data in the current set area.

If the recorded state of data in the current set area matches the completion condition, i.e., if the to-be-recorded data (small data) can be successively recorded in the current set area (“No” in step S26), the CPU 31 determines that the recording of data in the current set area has succeeded, and issues a notification that the recording of data in the current set area is complete (steps S27 and S112). In the notification of completion in step S27, the CPU 31 issues a notification of the completion for a unit of the number of recording instructions required to record the to-be-recorded data in the current set area. That is, a completion notification is issued for all recording instructions generated to record the to-be-recorded data in the current set area.

After issuing a notification of the completion of recording of data in the current set area, the CPU 31 determines whether or not recording of the to-be-recorded data (i.e., all small data) in the storage 5 is complete (step S28). If recording of the to-be-recorded data in the storage 5 is not complete (step S28: No), the operation of the information-processing device 1 returns to step S24. That is, the storage control device 3 receives the remaining small data from the information-processing device 1 and transmits the received remaining small data to the storage 5.

In a case where the recording of the to-be-recorded data in the storage 5 is complete (step S28: Yes), the CPU 31 determines whether or not the stopping operation of the storage control device 3 has been performed (step S29). As long as the stopping operation has not been performed (step S29: No), the above steps S22 to S28 are repeatedly executed. In a case where the stopping operation has been performed (step S29: Yes), the storage control device 3 stops operating.

### [5-3. Data-Recording Operation in Storage]

The data-recording operation in the storage 5 is described referring to FIGS. 8 and 9. First, the storage 5 determines whether or not a trigger has been received from the storage control device 3 (step S31 of FIG. 8). If a trigger has not been received (“No” in step S31), the storage 5 determines that there is no recording instruction to be received and continues to wait.

If a trigger has been received (step S31: Yes, step S105 in FIG. 9), the storage 5 determines that there is a recording instruction to be received, and receives the recording instruction from the storage control device 3 (step S32, steps S106 and S107). Specifically, the following process is executed. In a case where a trigger is received in the storage 5, the controller 55 of the storage 5 transmits an instruction acquisition request to the storage control device 3 (step S106).

In a case where an instruction acquisition request is received in the storage control device 3, a recording instruction is transmitted from the RAM 33 of the storage control device 3 to the controller 55 via the storage interface 37 of the storage control device 3 (step S107). The controller 55 records the received recording instruction in buffer memory, etc. (queueing). This process of receiving a recording instruction is repeatedly executed in proportion to the number of recording instructions stored in the RAM 33, i.e., the number of triggers received.

After receiving a recording instruction, the storage 5 receives small data that was generated by dividing the to-be-recorded data (step S33). Specifically, the following process is executed. The controller 55 analyzes the queued recording instruction and ascertains at which position (address) in the RAM 13 of the information-processing device 1 the small data to be received is stored. The controller 55 receives the small data to be received from the specified position in the RAM 13 via the storage control device 3 (step S108). For example, the small data to be received is temporarily stored in the RAM 33 of the storage control device 3, and the controller 55 receives the small data stored in the RAM 33.

The controller 55 then attempts to record the received small data on the page PA specified by the recording instruction (step S34). At this time, the controller 55 divides the received small data into fragments of the same size as the page PA, and sequentially records the fragments on the page PA.

If the small data is successfully recorded, i.e., if all fragments of the small data can be recorded on successive pages PA (“Yes” in step S35), the controller 55 issues a notification to the storage control device 3 that the data recording has succeeded (step S36, step S109).

The controller 55 then determines whether or not the recording of all the small data corresponding to the plurality of received recording instructions has been completed (step S37). That is, the controller 55 determines whether or not there is any small data remaining to be recorded in the flash memory 53. If there is any small data remaining to be recorded (“No” in step S37), the data-recording operation of the storage 5 returns to step S33. That is, the controller 55 continues recording the remaining small data.

If recording of all the small data has been completed (step S37: No), the controller 55 determines whether or not the stopping operation of the storage 5 has been performed (step S38). As long as the stopping operation has not been performed (step S38: No), steps S31 to S39 in FIG. 8 are repeatedly executed. If the stopping operation has been performed (step S38: Yes), the storage 5 stops operating.

If the recording of the small data has failed, i.e., if an intermediate fragment among the fragments divided from the small data cannot be recorded in the page PA (“No” in step S35), the controller 55 issues a notification to the storage control device 3 that the recording of the data has failed (step S39, step S110). The controller 55 issues a notification of small data recording failure regarding one recording instruction for recording the small data. That is, a notification is issued that data recording has succeeded or failed, for one recording instruction as a unit. After issuing a notification that data recording has failed, the controller 55 stops recording small data in the current set area.

As described above, if recording small data has failed during the recording of small data in the current set area (i.e., at a stage at which data recording has not ended up to the final page PA in the set area), the storage control device 3 issues a notification that the recording of data in the current set area has failed, for a unit of the number of recording instructions required to record the to-be-recorded data in the current set area. Recording of the small data that was to be recorded in the current set area is then resumed.

Therefore, after the recording of the small data in the current set area is stopped, the data-recording operation of the storage 5 returns to step S31. That is, the recording of the small data in the current set area is resumed. Specifically, a plurality of recording instructions for which the storage control device 3 issued an error notification are transmitted from the information-processing device 1 to the storage 5 via the storage control device 3, and the controller 55 receives and queues the recording instructions (steps S105 to S107). The small to-be-recorded data in response to the recording instructions is then sequentially transmitted from the information-processing device 1 to the storage 5 via the storage control device 3 (step S108).

In accordance with the recording instructions retransmitted and queued from the storage control device 3, the controller 55 records the small to-be-recorded data in response to the received recording instructions (i.e., the small data that failed to record in the current set area) in the flash memory 53. At this time, the controller 55 re-records the small to-be-recorded data in response to the received recording instructions in another set area different from the set area in which the recording of the small data failed (i.e., the current set area) (i.e., the controller 55 resumes recording of the small data from the first page PA of the other set area).

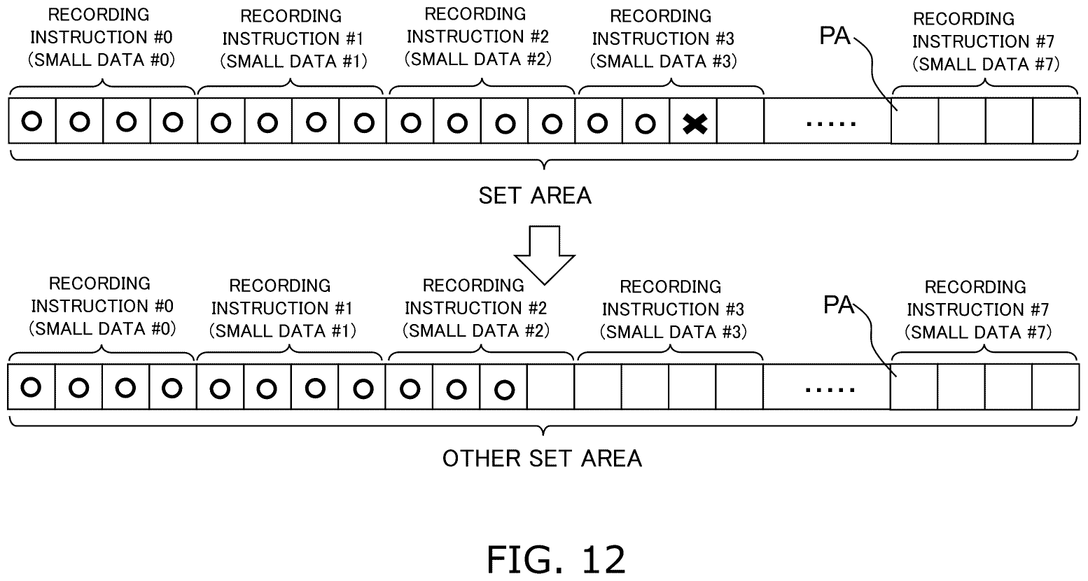

For example, as shown in FIG. 12, if the recording of small data #3 fails during the recording instruction #3 generated for recording small data #3, the controller 55 newly records small data #0 to #7 in another set area different from the set area where the data recording failed, in accordance with the successfully retransmitted recording instructions #0 to #7. FIG. 12 is a diagram schematically depicting an example of re-recording data that had failed to be recorded.

This prevents data fragmentation within a set area (e.g., one block BL), and suppresses subsequent execution of garbage collection. As a result, any decrease in the operating speed of the storage 5 can be suppressed.

### [6. Summary of Recording Operation]

A specific description is given below of how the to-be-recorded data is recorded by the recording operation described above. In the description below, it is assumed that the to-be-recorded data is divided into eight pieces of small data (F0, F1, F2, . . . . F7). It is also assumed that the size of the set area that determines the completion condition is one block BL. That is, it is assumed that the completion condition is that small data can be recorded successively within one block BL. It is also assumed that one block BL has a size equivalent to eight pieces of small data.

It is assumed that the to-be-recorded data, which has been divided into eight pieces of small data, is to be recorded in the order of small data F0, F1, F2, . . . , F7, starting from the first page PA of the block BL, as shown in FIG. 13. In this case, for example, if the recording of small data F3 fails ((A) in FIG. 13), other fragments cannot be recorded in the page PA in which the recording of the fragment of small data F3 failed. Therefore, if this page PA is skipped and the next fragment is recorded in another page PA, the continuity of the data will be lost. FIG. 10 is a diagram schematically depicting the recording of data in the data-recording system 100.

Therefore, in the data-recording system 100, if the recording of (a fragment of) small data in the page PA fails during the small data is being recorded in one block BL, it is determined that the recording of the small data in this block BL has failed, and the recording of data in the block BL is stopped at that point in time. Then, for example, the data is re-recorded in a new free block BL.

If the to-be-recorded data can be successively recorded in one block BL ((B) of FIG. 13), it is determined that the recorded state of the to-be-recorded data meets the completion condition, i.e., the recording of data in the block BL has been successful, and the recording of the to-be-recorded data in the block BL is complete.

As described above, in the data-recording system 100, in a case where data continuity within a set area is ensured, i.e., in a case where the to-be-recorded data can be recorded successively in a set area (in a case where all small data that was to be recorded in this set area has been successfully recorded), it is determined that the recording of data in this set area has been successful, and that the recording of data in this set area has completed.

On the other hand, in a case where data continuity within a set area cannot be ensured, i.e., in a case where the recording of specific small data fails during the recording of the to-be-recorded data in a set area, it is determined that the recording of data has failed for all of the small data that was to be recorded in this set area. In other words, in a case where the recording of data has failed for any of the recording instructions for recording the to-be-recorded data in a specific set area, it is determined that the recording of data has failed for not only the recording instruction with which recording failed, but for all of the recording instructions generated in order to record the to-be-recorded data in the specific set area.

In addition, in a case where data continuity within a specific set area cannot be ensured, small data that was to be recorded in the specific set area is recorded in a set area separate from the specific set area.

As described above, since data fragmentation in the storage 5 is suppressed, the execution of garbage collection is suppressed. As a result, any decrease in the operating speed of the storage 5 can be suppressed.

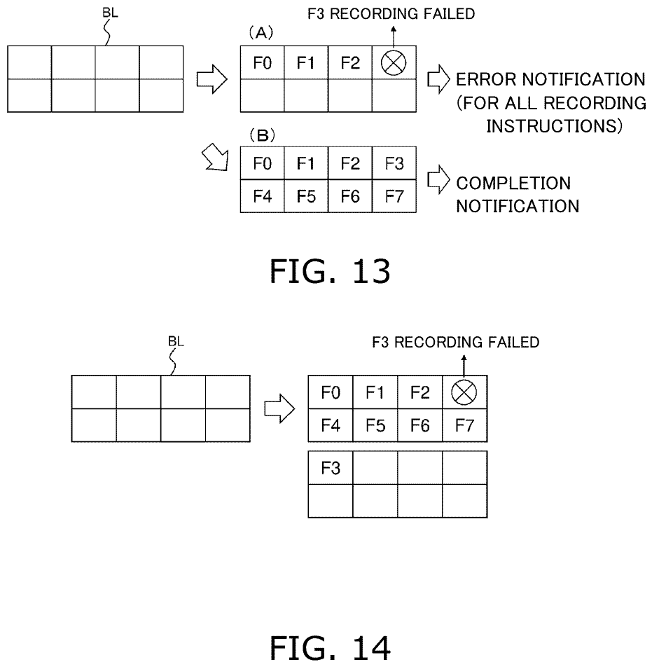

As a comparative example, in a case where the recording of the small data F3 in one block BL fails, the page PA where the small data F3 is to be recorded is skipped, the remaining small data is recorded in the specified page PA, and the small data F3 that failed to be recorded is recorded last, in which case the small data FO to F2 and F4 to F7 is recorded in a state of fitting in one block BL, and the small data F3 recorded last is recorded in another block BL (e.g., the next block BL), as shown in FIG. 14. FIG. 14 is a diagram schematically depicting the recording of data in a conventional example.

As shown in FIG. 14, originally, in a case where to-be-recorded data that can be recorded to fit into one block BL is recorded across two blocks BL, garbage collection occurs in a case where the to-be-recorded data is erased to make the two blocks BL free blocks.

### [7. Variation 1]

As a variation of the data-recording system 100, the controller 55 of the storage 5 may have the functions of the storage control device 3. That is, the controller 55 of the storage 5 may determine whether the completion condition is met and issues a notification that recording of data in a set area is complete or that there is an error in recording of data in a set area.

### [8. Variation 2]

Data that can be handled by the data-recording system 100 is not limited to video data. Even in a case where other data is recorded, the same effects as those described above can be obtained.

### [9. Characteristics of Present Disclosure]

(1) The data-recording system of the present disclosure comprises a storage and a storage control device. The storage is provided with flash memory and a controller. The flash memory has a plurality of blocks, each of which is a unit for erasing data. The blocks include a plurality of pages, each of which is a unit for recording data. The controller controls recording of data in the flash memory. The storage control device controls the storage.

In this data-recording system, the controller receives a plurality of recording instructions for recording to-be-recorded data in the flash memory from the storage control device, and records the to-be-recorded data in the flash memory in accordance with the received plurality of recording instructions.

In a case where the storage control device can successively record to-be-recorded data in a set area, the storage control device determines that data recording in the set area has been successful. The set area is an area in the flash memory having a predetermined number of pages. In a case where the storage control device determines that data recording in the set area has been successful, the storage control device issues a notification of completion of data recording in the set area, for a unit the number of recording instructions required to record the to-be-recorded data in the set area.

In a case where the storage control device is unable to successively record the to-be-recorded data in the set area, the storage control device determines that data recording in the set area has failed. In a case where the storage control device has determined that data recording in the set area has failed, the storage control device issues a notification of an error in data recording in the set area, for a unit of the number of recording instructions required to record the to-be-recorded data in the set area.

In the data-recording system of the present disclosure, in a case where the storage control device is able to successively record to-be-recorded data in a set area of the storage, the storage control device determines that data recording in the set area has succeeded, and issues a notification of the completion of data recording in the set area, for a unit of the number of recording instructions required to record the to-be-recorded data in the set area. In a case where to-be-recorded data cannot be successively recorded in a set area of the storage, the storage control device determines that data recording in the set area has failed, and issues a notification of an error in data recording in the set area, using as units the number of recording instructions required to record the to-be-recorded data in the set area. In other words, in a case where recording of to-be-recorded data has failed for any recording instruction for recording the to-be-recorded data in a specific set area, it is determined that data recording has failed not only for the recording instruction for which data recording failed, but for all recording instructions for recording the to-be-recorded data in the specific set area. This can suppress data fragmentation in the storage and suppress the execution of garbage collection. As a result, any decrease in the operating speed of the storage can be suppressed.

(2) In the data-recording system according to (1), the the block may be a unit of the set area. Fragmentation of data in the blocks can thereby be suppressed. As a result, it is possible to prevent the number of blocks required to record data from increasing from the initial number.

(3) In the data recording system according to (1) or (2), an amount of data that can be recorded in the blocks may be a unit of the set area. This can realize a set area without having to be aware of boundary positions of the blocks.

(4) In the data-recording system according to (1) to (3), in a case where an error notification has been issued, the storage control device may retransmit the plurality of recording instructions for which the error notification was issued. In this case, the controller, in accordance with the plurality of recording instructions retransmitted from the storage control device, records the to-be-recorded data according to the received plurality of recording instructions in another set area that is different from the set area in which the data was to be recorded but had failed. This can prevent data that has failed to be recorded from being forgotten to be recorded, and also to prevent data from being recorded in a fragmented state.

(5) In the data-recording system according to (1) to (4), the controller may issue a notification the storage control device of whether or not data recording has succeeded for each of a plurality of recording instructions. The storage control device 3 can thereby ascertain success or failure of the recording of data in recording instruction units.

(6) In the data-recording system according to (1) to (5), the storage may be included in the storage control device. This can realize an integrated data-recording system.

(7) In the data-recording system according to (1) to (6), the storage may be connected to the storage control device via a network. This can realize a data-recording system that remotely controls storage.

(8) The storage of the present disclosure comprises a flash memory and a controller. The flash memory has a plurality of blocks. The blocks include a plurality of pages, each of which is a unit for recording data. The controller controls the recording of data in the flash memory. In the storage, the controller receives a plurality of recording instructions for recording to-be-recorded data in the flash memory, and records the to-be-recorded data in the flash memory in accordance with the received plurality of recording instructions.

In the storage described above, in a case where it is determined that data recording in a set area has succeeded due to the to-be-recorded data being successively recorded in the set area, a notification of data recording completion is issued, for a unit of the number of recording instructions required in order to record the to-be-recorded data in the set area.

In a case where it is determined that data recording in a set area has failed due to the to-be-recorded data not being successively recorded in the set area, a notification of a data recording error is issued, for a unit of the number of recording instructions required to record the to-be-recorded data in the set area.

In the storage of the present disclosure, in a case where to-be-recorded data can be successively recorded in a set area of the storage, it is determined that data recording in the set area has succeeded, and a notification is issued of the completion of data recording in the set area, for a unit of the number of recording instructions required in order to record the to-be-recorded data in the set area. In a case where to-be-recorded data cannot be successively recorded in a set area, it is determined that data recording in the set area has failed, and a notification is issued of an error in data recording in the set area, for a unit of the number of recording instructions required to record the to-be-recorded data in the set area. In other words, in a case where recording of to-be-recorded data has failed for any recording instruction for recording the to-be-recorded data in a specific set area, it is determined that data recording has failed not only for the recording instruction for which data recording failed, but for all recording instructions for recording the to-be-recorded data in the specific set area. This can suppress data fragmentation in the storage and suppress the execution of garbage collection. As a result, any decrease in the operating speed of the storage can be suppressed.

(9) A control method of the present disclosure is a method of controlling a storage having a flash memory that has a plurality of blocks, which are units for erasing data. The blocks include a plurality of pages, which are units for recording data. The control method comprises:

(i) receiving a plurality of recording instructions for recording to-be-recorded data in the flash memory.

(ii) recording the to-be-recorded data in the flash memory in accordance with the received plurality of recording instructions.

(iii) In a case where the to-be-recorded data can be successively recorded in a set area, determining that data recording in the set area has succeeded, and issuing a notification of the completion of data recording in the set area, for a unit of the number of recording instructions required to record the to-be-recorded data in the set area.

(iv) In a case where the to-be-recorded data cannot be successively recorded in the set area, determining that data recording in the set area has failed, and issuing a notification of an error in data recording in the set area, for a unit of the number of recording instructions required to record the to-be-recorded data in the set area.

In the storage control method of the present disclosure, in a case where to-be-recorded data can be successively recorded in a set area of the storage, it is determined that data recording in the set area has succeeded, and a notification is issued of the completion of data recording in the set area, for a unit of the number of recording instructions required to record the to-be-recorded data in the set area. In a case where to-be-recorded data cannot be successively recorded in a set area, it is determined that data recording in the set area has failed, and a notification is issued of an error in data recording in the set area, for a unit of the number of recording instructions required to record the to-be-recorded data in the set area. In other words, in a case where recording of to-be-recorded data has failed for any recording instruction for recording the to-be-recorded data in a specific set area, it is determined that data recording has failed not only for the recording instruction for which data recording failed, but for all recording instructions for recording the to-be-recorded data in the specific set area. This can suppress data fragmentation in the storage and suppress the execution of garbage collection. As a result, any decrease in the operating speed of the storage can be suppressed.

### INDUSTRIAL APPLICABILITY

The present disclosure can be applied to a data-recording system for recording data in a storage.

### REFERENCE NUMERALS

100 Data-recording system
1 Information-processing device

### 11 CPU

### 13 RAM

15 Storage device
17 Video interface
19 Network interface
3 Storage control device

### 31 CPU

### 33 RAM

35 Storage device
37 Storage interface
39 Network interface

### 5 Storage

51 Access port
53 Flash memory

### 55 Controller

57 Storage unit
7 Video output device
RA Recording area
SA Spare area
UA Usable area

### BL Block

F0-F7 Small data

1. A data-recording system comprising:
a storage having
a flash memory having a plurality of blocks, each of which is a unit for erasing data, and each of which includes a plurality of pages, each of which is a unit for recording data; and
a controller configured to control recording of data in the flash memory; and
a storage control device configured to control the storage, wherein:
the controller is configured to
receive a plurality of recording instructions for recording to-be-recorded data in the flash memory from the storage control device, and
record the to-be-recorded data in the flash memory in accordance with the received plurality of recording instructions;
the storage control device is configured to,
in a case where the to-be-recorded data can be successively recorded in a set area having a predetermined number of pages, determine that data recording in the set area has succeeded, and issue a notification of the completion of data recording in the set area for a unit of the number of recording instructions required to record the to-be-recorded data in the set area, and
in a case where the to-be-recorded data cannot be successively recorded in the set area, determine that data recording in the set area has failed, and issue a notification of an error in data recording in the set area for a unit of the number of recording instructions required to record the to-be-recorded data in the set area.

2. The data-recording system according to claim 1, wherein the block is a unit of the set area.

3. The data-recording system according to claim 2, wherein an amount of data that can be recorded in the block is a unit of the set area.

4. The data-recording system according to claim 1, wherein,
in a case where a notification of the error has been issued,
the storage control device retransmits to the storage a plurality of recording instructions for which the error notification was issued, and
the controller, in accordance with the plurality of recording instructions retransmitted from the storage control device, records to-be-recorded data according to the received plurality of recording instructions in another set area, which is different from the set area in which the data was to be recorded but had failed.

5. The data-recording system according to claim 1, wherein the controller issues a notification to the storage control device of whether or not data recording has succeeded for each of the plurality of recording instructions.

6. The data-recording system according to claim 1, wherein the storage is included in the storage control device.

7. The data-recording system according to claim 1, wherein the storage is connected to the storage control device via a network.

8. A storage comprising:
a flash memory having a plurality of blocks, each of which is a unit for erasing data, and each of which includes a plurality of pages, each of which is a unit for recording data; and
a controller configured to control recording of data in the flash memory,
wherein:
the controller is configured to
receive a plurality of recording instructions for recording to-be-recorded data in the flash memory,
record the to-be-recorded data in the flash memory in accordance with the received plurality of recording instructions,
in a case where it is determined that data recording in a set area having a predetermined number of pages has succeeded due to the to-be-recorded data being successively recorded in the set area, a notification of data recording completion is issued for a unit of the number of recording instructions required in order to record the to-be-recorded data in the set area, and
in a case where it is determined that data recording in the set area has failed due to the to-be-recorded data not being continuously recorded in the set area, a notification of a data recording error is issued for a unit of the number of recording instructions required to record the to-be-recorded data in the set area.

9. A method of controlling a storage having a flash memory having a plurality of blocks, each of which is a unit for erasing data, and each of which includes a plurality of pages, each of which is a unit for recording data, the control method comprising:
receiving a plurality of recording instructions for recording to-be-recorded data in the flash memory;
recording the to-be-recorded data in the flash memory in accordance with the received plurality of recording instructions;
in a case where the to-be-recorded data can be successively recorded in a set area having a predetermined number of pages, determining that data recording in the set area has succeeded, and issuing a notification of the completion of data recording in the set area for a unit of the number of recording instructions required in order to record the to-be-recorded data in the set area; and
in a case where the to-be-recorded data cannot be successively recorded in the set area, determining that data recording in the set area has failed, and issuing a notification of an error in data recording in the set area for a unit of the number of recording instructions required to record the to-be-recorded data in the set area.
